(19) United States
(12) Patent Application Publication
(10) Pub. No.: US 2022/0327063 A1
(43) Pub. Date: Oct. 13, 2022

(54) VIRTUAL MEMORY WITH DYNAMIC SEGMENTATION FOR MULTI-TENANT FPGAS

(71) Applicant: Nokia Solutions and Networks Oy, Espoo (FI)

(72) Inventors: Andrea ENRICI, Bourg la Reine (FR); Julien LALLET, Lannion (FR)

(73) Assignee: Nokia Solutions and Networks Oy, Espoo (FI)

(21) Appl. No.: 17/224,622

(22) Filed: Apr. 7, 2021

(51) Int. Cl. G06F 12/1036; H03K 19/17704; H03K 19/17728; H03K 19/17756; G06F 12/1009; H03K 19/1776

(52) U.S. Cl. CPC G06F 12/1036; H03K 19/17708; H03K 19/17728; H03K 19/17756; G06F 12/1009; H03K 19/1776; G06F 2212/652

(57) ABSTRACT

At least one example embodiment provides a programmable logic device comprising: a plurality of reconfigurable slots programmed to execute functions requested by a plurality of users, the plurality of reconfigurable slots allocated among the plurality of users; a memory divided into a plurality of memory segments, the plurality of memory segments allocated among the plurality of reconfigurable slots; and a memory management circuit configured to dynamically adjust the plurality of memory segments based on at least one of activity or memory requirements of the plurality of reconfigurable slots.

### BACKGROUND

A field-programmable gate array (FPGA) is an integrated circuit designed to be configured or re-configured after manufacture. FPGAs contain an array of Configurable Logic Blocks (CLBs), and a hierarchy of reconfigurable interconnects that allow these blocks to be wired together, like many logic gates that can be inter-wired in different configurations. CLBs may be configured to perform complex combinational functions, or simple logic gates like AND and XOR. CLBs also include memory blocks, which may be simple flip-flops or more complete blocks of memory, and specialized Digital Signal Processing blocks (DSPs) configured to execute some common operations (e.g., filters).

### SUMMARY

The scope of protection sought for various example embodiments of the disclosure is set out by the independent claims. The example embodiments and/or features, if any, described in this specification that do not fall under the scope of the independent claims are to be interpreted as examples useful for understanding various embodiments.

At least one example embodiment provides a programmable logic device comprising: a plurality of reconfigurable slots programmed to execute functions requested by a plurality of users, the plurality of reconfigurable slots allocated among the plurality of users; a memory divided into a plurality of memory segments, the plurality of memory segments allocated among the plurality of reconfigurable slots; and a memory management circuit configured to dynamically adjust the plurality of memory segments based on at least one of activity or memory requirements of the plurality of reconfigurable slots.

At least one example embodiment provides a programmable logic device comprising: a plurality of reconfigurable slots programmed to execute functions requested by a plurality of users; a memory including a plurality of variable-sized segments; means for assigning a variable-sized segment, from among the plurality of variable-sized segments, to each of a plurality of reconfigurable slots, each of the plurality of users assigned to at least one of the plurality of reconfigurable slots; means for determining that a first reconfigurable slot, among the plurality of reconfigurable slots, has become inactive; and means for dynamically adjusting sizes of the plurality of variable-sized segments in response to determining that the first reconfigurable slot has become inactive.

According to one or more example embodiments, the memory management circuit may be configured to adjust a spatial allocation of the plurality of memory segments among the plurality of reconfigurable slots based on the at least one of activity or memory requirements of the plurality of reconfigurable slots.

The memory management circuit may be configured to adjust the spatial allocation of the plurality of memory segments by adjusting a size of one or more of the plurality of memory segments. In adjusting the size of the one or more of the plurality of memory segments, the memory management circuit may adjust a length (or size) and change a start and/or an end address of the one or more of the plurality of memory segments.

Each of the plurality of memory segments may have a variable segment size.

The plurality of memory segments may include a first memory segment allocated to a first reconfigurable slot among the plurality of reconfigurable slots. The memory management circuit may be configured to: determine that the first reconfigurable slot has become inactive, and reallocate the first memory segment among remaining ones of the plurality of reconfigurable slots in response to determining that the first reconfigurable slot has become inactive.

The memory management circuit may be configured to: determine that the first reconfigurable slot has become active after having been inactive, and reallocate a portion of at least one of the plurality of memory segments to the first reconfigurable slot in response to determining that the first reconfigurable slot has become active.

The plurality of memory segments may include a first memory segment allocated to a first reconfigurable slot among the plurality of reconfigurable slots. The memory management circuit may be configured to: determine that the memory requirements for the first reconfigurable slot have changed, and reallocate, to the first reconfigurable slot, at least a portion of a memory segment allocated to a second reconfigurable slot in response to determining that the memory requirements for the first reconfigurable slot have changed.

The memory management circuit may be configured to manage the plurality of memory segments independent of an external host device.

The memory management circuit may include: a segment descriptor table storing segment descriptor information for the plurality of memory segments, wherein segment descriptor information for a memory segment, among the plurality of memory segments, includes at least a segment length of the memory segment, and the segment descriptor table is configured to output the segment descriptor information for the memory segment based on received virtual address information including a segment number indicative of the memory segment.

The segment length parser circuit may be configured to: parse the segment descriptor information for the memory segment to obtain parsed segment descriptor information, and access the memory segment based on the parsed segment descriptor information.

The segment length may include a plurality of bits, and the segment length parser circuit may be configured to parse the segment descriptor information for the memory segment by masking a portion of the plurality of bits based on a number of the plurality of reconfigurable slots that are currently active.

The segment length may include a plurality of bits, and the segment length parser circuit may be configured to dynamically adjust sizes of the plurality of memory segments based on a masking of a portion of the plurality of bits based on a number of the plurality of reconfigurable slots that are currently active.

Segment descriptor information may include virtual address information for the memory segment, and the segment length parser circuit may be configured to dynamically parse the virtual address information for the memory segment based on a number of the plurality of reconfigurable slots that are currently active and a variable size of the plurality of memory segments.

At least one example embodiment provides a method for managing memory at a programmable logic device including a plurality of reconfigurable slots and a memory, the plurality of reconfigurable slots programmed to execute functions requested by a plurality of users, and the memory including a plurality of variable-sized segments, wherein the method comprises: assigning a variable-sized segment, from among the plurality of variable-sized segments, to each of a plurality of reconfigurable slots, each of the plurality of users assigned to at least one of the plurality of reconfigurable slots; determining that a first reconfigurable slot, among the plurality of reconfigurable slots, has become inactive; and dynamically adjusting sizes of the plurality of variable-sized segments in response to determining that the first reconfigurable slot has become inactive.

According to one or more example embodiments, the first variable-sized memory segment may be allocated the first reconfigurable slot, a second variable-sized memory segment is allocated a second reconfigurable slot, among the plurality of reconfigurable slots, and the dynamically adjusting includes re-allocating at least a portion of the first variable-sized memory segment to the second reconfigurable slot to increase a size of the second variable-sized memory segment in response to determining that the first reconfigurable slot has become inactive.

The method may further include determining that the first reconfigurable slot has become active after having been inactive; and wherein the dynamically adjusting includes creating a first variable-sized memory segment allocated to the first reconfigurable slot by reallocating at least a portion of at least a second variable-sized memory segment allocated to a second reconfigurable slot in response to determining that the first reconfigurable slot has become active.

The dynamically adjusting may dynamically adjust the sizes of the plurality of variable-sized segments independent of an external host device.

The determining may determine that the first reconfigurable slot has become inactive based on a status bit indicating an activity of the first reconfigurable slot.

The programmable logic device may be a Field Programmable Gate Array (FPGA).

At least one other example embodiment provides a method for access a main memory of a programmable logic device including a plurality of partial reconfiguration slots, the method comprising: accessing segment descriptor information associated with a first partial reconfiguration slot among the plurality of partial reconfiguration slots based on virtual address information received from the first partial reconfiguration slot; parsing the segment descriptor information based on a number of active partial reconfiguration slots among the plurality of partial reconfiguration slots to obtain parsed segment descriptor information; accessing a page table for the first partial reconfiguration slot based on the parsed segment descriptor information to obtain one or more entries for accessing the main memory; and accessing the main memory based on the one or more entries for accessing the main memory.

At least one other example embodiment provides a controller for accessing a main memory of a programmable logic device including a plurality of partial reconfiguration slots, the controller comprising: means for accessing segment descriptor information associated with a first partial reconfiguration slot among the plurality of partial reconfiguration slots based on virtual address information received from the first partial reconfiguration slot; means for parsing the segment descriptor information based on a number of active partial reconfiguration slots among the plurality of partial reconfiguration slots to obtain parsed segment descriptor information; means for accessing a page table for the first partial reconfiguration slot based on the parsed segment descriptor information to obtain one or more entries for accessing the main memory; and means for accessing the main memory based on the one or more entries for accessing the main memory.

At least one other example embodiment provides a programmable logic device comprising: a plurality of partial reconfiguration slots, a main memory and a controller. The controller is configured to: access segment descriptor information associated with a first partial reconfiguration slot among the plurality of partial reconfiguration slots based on virtual address information received from the first partial reconfiguration slot; parse the segment descriptor information based on a number of active partial reconfiguration slots among the plurality of partial reconfiguration slots to obtain parsed segment descriptor information; access a page table for the first partial reconfiguration slot based on the parsed segment descriptor information to obtain one or more entries for accessing the main memory; and access the main memory based on the one or more entries for accessing the main memory.

### BRIEF DESCRIPTION OF THE DRAWINGS

Example embodiments will become more fully understood from the detailed description given herein below and the accompanying drawings, wherein like elements are represented by like reference numerals, which are given by way of illustration only and thus are not limiting of this disclosure.

FIG. 1 is a block diagram illustrating a field programmable gate array (FPGA) architecture according to example embodiments.

FIG. 2 is a block diagram illustrating an example memory segmentation of a FPGA memory according to example embodiments.

FIG. 3 is a block diagram illustrating another example memory segmentation of a FPGA memory according to example embodiments.

FIG. 4 is a block diagram illustrating yet another example memory segmentation of a FPGA memory according to example embodiments.

FIG. 5 illustrates a virtual address format according to example embodiments.

FIG. 6 illustrates a segment descriptor format according to example embodiments.

FIG. 7 is a block diagram illustrating elements of a memory manager and a main memory according to example embodiments.

FIG. 8 is a block diagram illustrating a segment length parser according to example embodiments.

FIG. 9 is a flow chart illustrating a method according to example embodiments.

FIG. 10 is a flow chart illustrating another method according to example embodiments.

FIG. 11 is a flow chart illustrating yet another method according to example embodiments.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. The use of similar or identical reference numbers in the various drawings is intended to indicate the presence of a similar or identical element or feature.

### DETAILED DESCRIPTION

Various example embodiments will now be described more fully with reference to the accompanying drawings in which some example embodiments are shown.

Detailed illustrative embodiments are disclosed herein. However, specific structural and functional details disclosed herein are merely representative for purposes of describing example embodiments. The example embodiments may, however, be embodied in many alternate forms and should not be construed as limited to only the embodiments set forth herein.

Accordingly, while example embodiments are capable of various modifications and alternative forms, the embodiments are shown by way of example in the drawings and will be described herein in detail. It should be understood, however, that there is no intent to limit example embodiments to the particular forms disclosed. On the contrary, example embodiments are to cover all modifications, equivalents, and alternatives falling within the scope of this disclosure. Like numbers refer to like elements throughout the description of the figures.

In modern cloud-based data centers, servers are equipped with reconfigurable hardware (e.g., field-programmable gate arrays (FPGAs)), which is used to accelerate the computation of data-intensive or time-sensitive applications. In webscale architectures FPGAs may be used to accelerate the network (e.g., ensure fast packet forwarding) and/or accelerate the data (e.g., central processing unit (CPU) workload) processing.

FPGA reconfigurability is referred to as “partial reconfiguration,” (PR) which supposes that parts of FPGA hardware may be reconfigured while the FPGA is running (in operation). The partial reconfiguration is performed on allocated portions of a FPGA chip (or FPGA reconfigurable logic), which are known as “partial reconfiguration slots.” In particular, partial reconfiguration allows for multiple tenants in a data center to use/share a single FPGA. In one example, partial reconfiguration slots may be programmed/reprogrammed using Programming Protocol-independent Packet Processors (P4) to perform network functions or services (e.g., routing, switching, application processing, etc.).

P4 is a novel data-plane programming language enabling data-plane programming during the exploitation lifetime of a device. P4 provides a paradigm, which differs from the approach used by traditional Application Specific Integrated Circuit (ASIC)-based devices (e.g., switches). Furthermore, P4 is target-independent in that the programming language may be applied to CPUs, FPGAs, system-on-chips (SoCs), etc., and is protocol-independent in that the programming language supports all data-plane protocols and may be used to develop new protocols.

When implemented on FPGAs, P4 applications allow for reprogramming of only some portions of a FPGA (some or all of the partial reconfiguration slots), without stopping (or interrupting) operation of the device.

FPGAs with P4 modules in their partial reconfiguration slots may be interconnected in a webscale cloud.

P4 applications are composed of P4 modules that use different reconfigurable portions of FPGA's resources.

Although discussed herein with regard to P4 modules and workloads, example embodiments should not be limited to this example. Rather, example embodiments may be applicable to any kind of workload.

As a result of FPGA reconfigurability, each FPGA accelerator in a webscale cloud may be configured to contain n partial reconfiguration slots. As mentioned above, these partial reconfiguration slots may be dynamically reconfigured during operation of the FPGA.

For FPGAs, memory virtualization decouples a FPGA's volatile random access memory (RAM) resources from individual partial reconfiguration slots and/or users (tenants), and then aggregates the memory resources into a virtualized memory pool available to any slot and/or user as needed. The virtualized memory pool is accessed by the FPGA operating system (OS) or applications running on top of the FPGA OS. The virtualized memory pool may be utilized as a high-speed cache, a messaging layer, and/or a relatively large, shared memory resource for a FPGA server and/or FPGA application.

Memory virtualization enables overcoming of physical memory limitations, which is a common bottleneck in software performance. With this capability integrated into a network, FPGA applications may take advantage of larger amounts of memory to improve overall performance, system utilization, increase memory usage efficiency, enable new use cases, etc. Software at the memory pool user-end allows slots and/or users to connect to the memory pool to contribute memory, store and/or retrieve data (perform memory access operations).

As mentioned similarly above, the memory pool may be accessed at the application level or operating system level. At the application level, the memory pool may be accessed through an application programming interface (API) or as a file system to create a high-speed shared memory cache. At the operating system level, a page cache may utilize the memory pool as a (e.g., relatively large) memory resource that is faster than local or network storage (e.g., hard-disk or the like).

In the high-performance computing (HPC) domain, sophisticated frameworks allow for integrating FPGA operation into the execution model of a general- purpose host processor (e.g., a server's CPU). These frameworks grant the FPGA coherent access to the virtual memory of the host, thereby enabling the acceleration of critical parts of applications started on the host.

Conventionally, however, FPGA virtual memory management can only be initiated by the host system. This makes the FPGA memory a de facto slave unit of the host system. Moreover, the virtual address space of the FPGA and the virtual address space of the server CPU are shared. Consequently, in the conventional art, the FPGA cannot be managed as an independent computing unit.

One or more example embodiments enable virtualization of a (multi-tenant or multi-user) FPGA memory architecture (e.g., RAM memory) independent of the (virtual) memory architecture of a host server CPU.

In more detail, for example, one or more example embodiments provide a virtual memory management system and/or method for a multi-tenant FPGA. In at least one example embodiment, the FPGA's memory hierarchy is managed at the FPGA independently of the host memory hierarchy managed by the host. The FPGA main memory may be divided into virtual memory segments, each assigned to a partial reconfiguration slot of the FPGA. To reduce latency of page faults, the size of the memory segments may vary (be adjusted) dynamically based on activity of the partial reconfiguration slots. In this context, unlike memory managed by a host OS, a limited and known number of tenants may access the physical memory, which provides additional open space for more efficient memory management.

To this end, according to example embodiments, a memory manager may divide the FPGA main memory into segments, one per partial reconfiguration slot, to allocate or assign a separate (virtual) address space (virtual memory segment) to each partial reconfiguration slot. The memory manager may dynamically adjust a spatial allocation of the virtual memory segments by adjusting a physical allocation of memory resources among the plurality of reconfigurable slots. To this end, the memory manager may dynamically adjust the size of one or more of the virtual memory segments, as needed based on the number of active partial reconfiguration slots and the memory needs of the active partial reconfiguration slots.

In more detail, the memory manager (e.g., at system boot) may initially assign a variable portion (memory segment length or size) of the FPGA main memory to each partial reconfiguration slot based on memory needs and/or requirements of the partial reconfiguration slots. The memory manager may then resize virtual memory segments based on the activity (or inactivity) of the partial reconfiguration slots at the FPGA. In one example, the memory manager may add virtual memory segments, remove memory segments and/or adjust the size of existing memory segments assigned to the partial reconfiguration slots based on the activity (or inactivity) of the partial reconfiguration slots at the FPGA. In one example, if a partial reconfiguration slot has been inactive (the FPGA resources of the partial reconfiguration slot have not been used) for a threshold time period (e.g., configurable by FPGA software), then the memory segment assigned to the inactive partial reconfiguration slot may be re-allocated to increase the size of the memory segments for the remaining active partial reconfiguration slots as needed. When the inactive partial reconfiguration slot becomes active (the FPGA resources of the partial reconfiguration slot are again in use), portions of the memory segments allocated to the previously active partial reconfiguration slots may be reallocated to the now active partial reconfiguration slot, thereby decreasing the size of memory segments for the previously active partial reconfiguration slots (e.g., down to the initial configuration in which memory segments have minimum or default size).

One or more example embodiments also provide mechanisms, methods and/or data structures for implementing and accessing a virtualized FPGA main memory, such as the one discussed above.

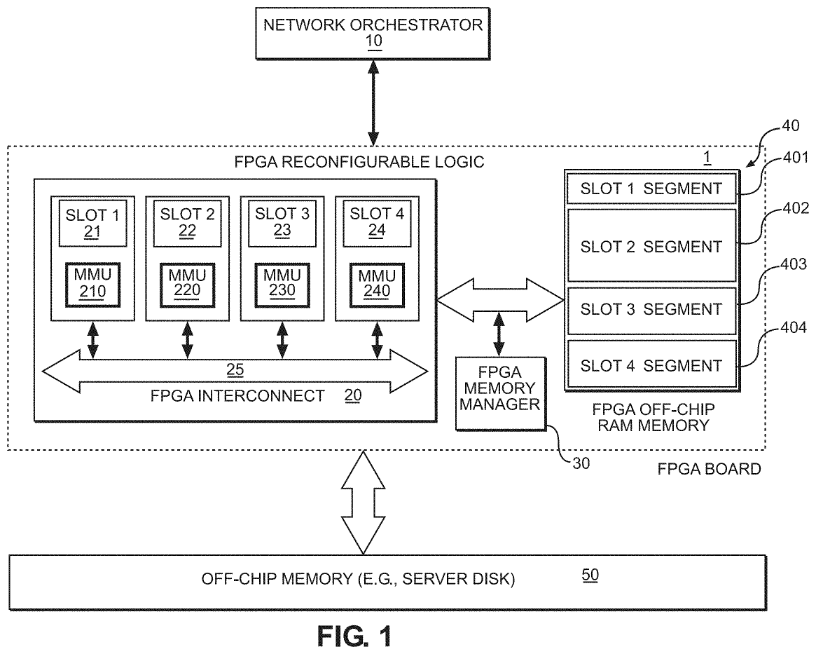

FIG. 1 is a block diagram illustrating a FPGA architecture according to example embodiments.

Referring to FIG. 1, the FPGA architecture 1 includes a FPGA 20, FPGA memory manager 30, FPGA off-chip memory (also referred to as a main memory) 40, and off-chip memory 50. The FPGA 20 includes a plurality of partial reconfiguration slots (also referred to as reconfigurable resources) 21, 22, 23 and 24, and a FPGA bus (or interconnect) 25 interconnecting the partial reconfiguration slots 21, 22, 23 and 24. Each of the partial reconfiguration slots 21, 22, 23 and 24 includes a respective one of memory management units (MMUs) 210, 220, 230 and 240. The FPGA architecture 1 is in two-way communication with a network orchestrator 10.

The main memory 40 may be a computer readable storage medium including a RAM, read only memory (ROM), and/or a permanent mass storage device, such as a disk or flash drive. The main memory 40 will be discussed in more detail later. The off-chip memory 50 may be a physical memory at a server or the like (e.g., server hard disk).

Each of the partial reconfiguration slots 21-24 also includes a set of reconfigurable resources (e.g., Digital Signal Processors (DSPs), memory blocks, logic blocks, etc.) and may be allocated to a module for use by a respective user. The amount of resources per slot may vary. The partial reconfiguration slots 21-24 may execute applications (e.g., network applications) requested by the network orchestrator 10.

The MMUs 210-240 enable the main memory 40 to be shared among the partial reconfiguration slots 21-24 by functioning as interfaces to communicate with the memory manager 30 and the main memory 40. In one example, among other things, the MMU in a given slot may perform virtual memory management for the partial reconfiguration slot by exchanging virtual address information with the memory manager 30 to access (read/write from/to) the main memory 40 as needed.

The FPGA memory manager 30 is a central memory manager for the FPGA 20. According to one or more example embodiments, the FPGA memory manager 30 facilitates access to the main memory 40 for the partial reconfiguration slots 21-24 as needed based on virtual memory address information provided by the MMUs 210-240. Additionally, as mentioned above, the FPGA memory manager 30 may divide the main memory 40 into memory segments, one per partial reconfiguration slot, thus granting/allocating a separate (virtual) address space to each partial reconfiguration slot. The FPGA memory manager 30 may also dynamically add memory segments, remove memory segments and/or adjust the size of each existing virtual memory segment based on the number of active partial reconfiguration slots and memory needs of the active partial reconfiguration slots. For example, the memory manager 30 may update the segment length for a memory segment allocated to a partial reconfiguration slot based on the actual number of active partial reconfiguration slots and a smart monitoring of slot accesses to the virtual memory segment.

Although illustrated as part of the FPGA 20 in FIG. 1, the memory manager 30 may be implemented by processing or control circuitry such as, but not limited to, one or more processors, one or more Central Processing Units (CPUs), one or more controllers, one or more arithmetic logic units (ALUs), one or more digital signal processors (DSPs), one or more microcomputers, one or more field programmable gate arrays (FPGAs), one or more System-on-Chips (SoCs), one or more programmable logic units (PLUs), one or more microprocessors, one or more Application Specific Integrated Circuits (ASICs), or any other device or devices capable of responding to and executing instructions in a defined manner.

Example functionality of the FPGA memory manager 30 will be discussed in more detail later.

In the example shown in FIG. 1, the main memory 40 is a RAM memory having virtual memory segmentation including a plurality of virtual memory segments 401-404. In this example, memory segment 401 is allocated to partial reconfiguration slot 21, memory segment 402 is allocated to partial reconfiguration slot 22, memory segment 403 is allocated to partial reconfiguration slot 23, and memory segment 404 is allocated to partial reconfiguration slot 24. The virtual memory segmentation shown in FIG. 1 may be a default memory segmentation at time tO (e.g., at system boot or initialization).

Although only four partial reconfiguration slots and four memory segments are shown in FIG. 1, example embodiments should not be limited to this example.

In the example shown in FIG. 1, at time t0, the size of the memory segment allocated to a respective partial reconfiguration slots may be based on the memory footprint of the respective partial reconfiguration slots. For example, the memory manager 30 may allocate the largest memory segment (memory segment 402) to partial reconfiguration slot 22 because this partial reconfiguration slot has the largest memory needs or requirement in terms of memory area. By contrast, the memory manager 30 may allocate the smallest memory segment (memory segment 401) to partial reconfiguration slot 21 because this partial reconfiguration slot has the smallest memory need or requirement relative to the other partial reconfiguration slots. In another example, at time t0, the main memory 40 may be divided equally among the partial reconfiguration slots 21-24 such that each of the memory segments has the same size or length.

Although not shown in FIG. 1, the memory manager 30 and/or the main memory 40 may include virtual memory management data structures (e.g., segmentation and/or page tables) for the FPGA 20. The virtual memory management data structures are data structures utilized to translate a virtual memory address into a physical memory address.

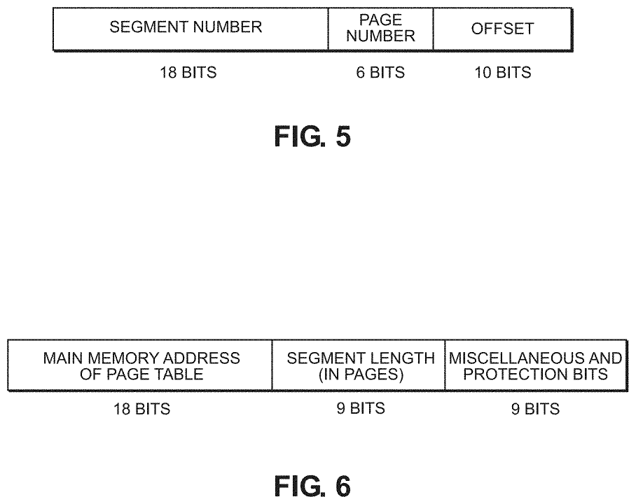

FIG. 5 illustrates a virtual address format according to example embodiments. As shown in FIG. 5, the virtual address includes an 18 bit segment number, a 6 bit page number and a 10 bit offset. The 18 bit segment number identifies an applicable virtual memory segment among the plurality of virtual memory segments 401-404 in the main memory 40. The 6 bit page number identifies a page within a memory segment, and the 10bit offset identifies a memory word within a given page.

FIG. 6 illustrates a segment descriptor format according to example embodiments. The segment descriptor (also referred to as segment descriptor information) provides information regarding a given virtualized memory segment. As shown in FIG. 6, the segment descriptor includes an 18 bit main memory address of a page table, a 9 bit segment length (in pages) and 9 miscellaneous and protection bits. The 18 bit main memory address of the page table indicates an address at which the page table for the partial reconfiguration slot requesting the memory operation is stored. The 9 bit segment length is a length of the virtual memory segment allocated to the partial reconfiguration slot. The 9 miscellaneous and protection bits are used to encode information related to memory protection (e.g., read and write permissions) and to encode miscellaneous information such as the page size (e.g., 1024 or 64 words), flags related to paging information for the segment (e.g., flag =0if the segment is paged, flag =1 if the segment is not paged).

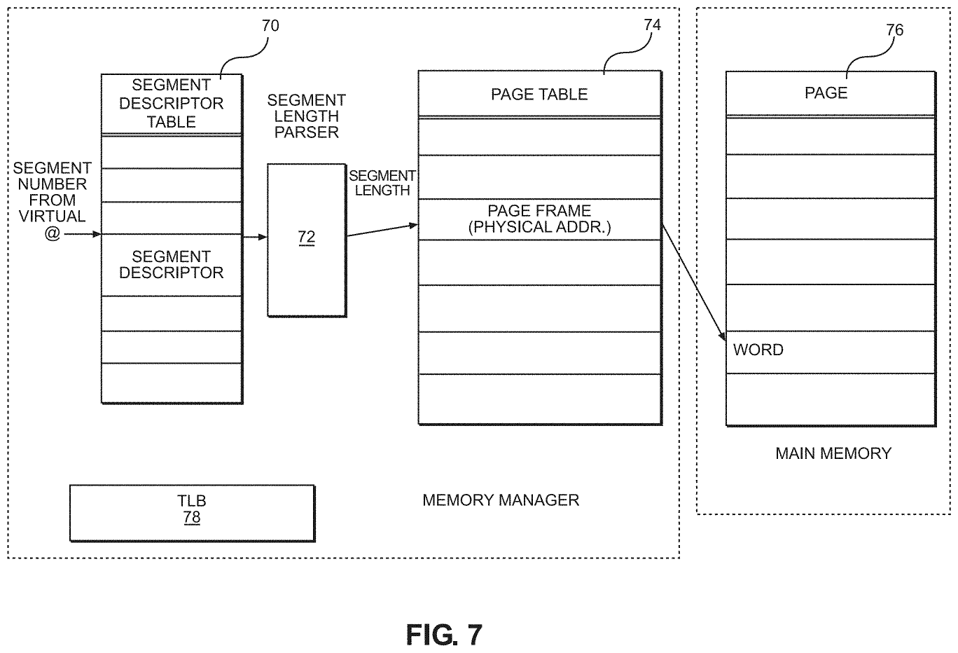

FIG. 7 is a block diagram illustrating elements of the memory manager 30 and the main memory 40 according to example embodiments.

Referring to FIG. 7, the memory manager 30 includes at least one segment descriptor table 70, a segment length parser (also referred to as the segment length parser circuit) 72 and a translation lookaside buffer (TLB) 78.

The TLB 78 may be a single (relatively large) TLB for all of the FPGA partial reconfiguration slots 21-24. The TLB 78 stores commonly used virtual addresses and metadata for the partial reconfiguration slots 21-24. The TLB 78 acts as a cache memory before accessing the segment descriptor table 70.

The segment descriptor table 70 stores segment descriptor information for the plurality of memory segments 401-404 in association with segment numbers identifying the memory segments 401-404. As shown and discussed above with regard to FIG. 6, the segment descriptor information for a memory segment may include 18 bit main memory address of a page table, a 9 bit segment length and a 9 miscellaneous and protection bits. The segment descriptor table 70 is configured to identify segment descriptor information for a virtual memory segment based on the segment number included in received virtual address information from a MMU of a given partial reconfiguration slot, and to output the segment descriptor information for the identified memory segment to the segment length parser 72 as needed for address translation.

The segment length parser 72 is configured to selectively parse (as needed) the segment descriptor information obtained from the segment descriptor table 70 to obtain a parsed segment descriptor information. The memory manager 30 is then configured to access the page table 74 for the partial reconfiguration slot based on the segment descriptor information (parsed or unparsed) to obtain the page frame for the page 76 to be accessed in the main memory 40. The memory manager 30 may then access the appropriate portion (word) in the main memory 40 based on the page frame obtained from the page table 74.

Although shown in FIG. 7 as being part of the memory manager 30, one or more of the segment descriptor table 70, the segment length parser 72, the page table 74 and/or the TLB 78 may be implemented and/or stored elsewhere (e.g., in the main memory 40).

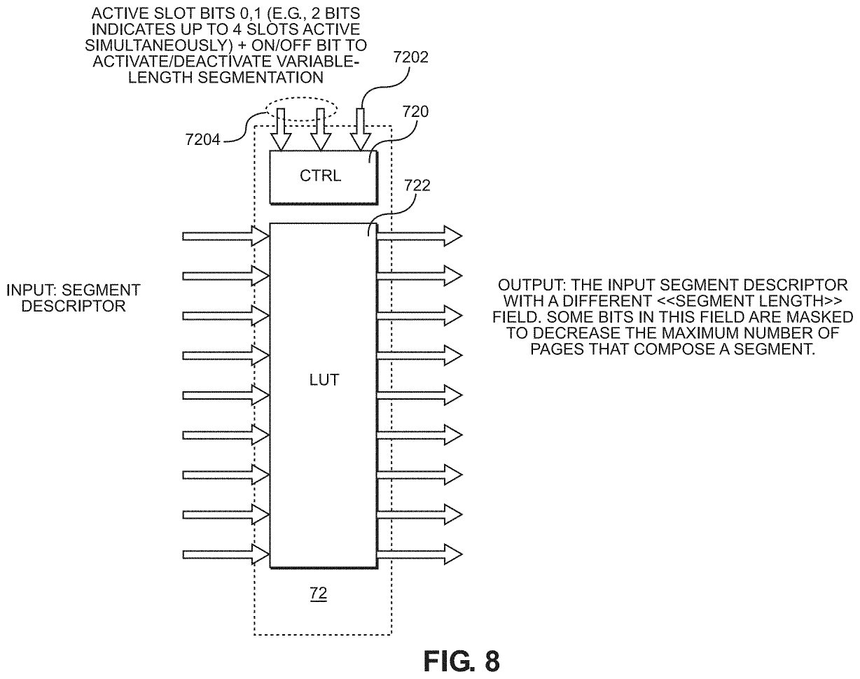

FIG. 8 is a block diagram illustrating a segment length parser according to example embodiments.

Referring to FIG. 8, the segment length parser 72 includes a look-up table (LUT) 722 and a controller (or control circuit) 720. The controller 720 may be a dedicated controller for the segment length parser 72. The controller 720 may control output of the LUT 722 based on active slot bits 7204 and an on/off bit (also referred to as an on/off indicator bit) 7202. The active slot bits 7204 indicate the number of currently active partial reconfiguration slots at the FPGA 20. In one example, 2 bits indicate up to 4 partial reconfiguration slots that are concurrently or simultaneously active.

The on/off bit 7202 indicates a current state (ON/OFF) of the segment length parser 72 for a given partial reconfiguration slot. An on/off bit for each partial reconfiguration slot may be stored in a control register (not shown) at the FPGA 20. The variable length segmentation function at the segment length parser 72 is activated or deactivated for a given partial reconfiguration slot based on the state (ON/OFF) of the on/off bit 7202 associated with the partial reconfiguration slot. Accordingly, the segment length parser 72 is configured to selectively parse segment length information output from the segment descriptor table 70.

The LUT 722 implements a mapping function that takes as input a key and produces a value. The input key is composed of the input segment descriptor and the active slot bits 7204 encoding the active slots. The output value produced by the LUT 722 is the “segment length” field (FIG. 6) that replaces the field in the input segment descriptor. A linear mapping function is one that assigns equal segment lengths. For instance, given a FPGA with n slots, the output segment length is the size of the available main memory divided by n.

According to example embodiments, activity of partial reconfiguration slots may be monitored continuously by a FPGA reconfiguration controller (not shown). The FPGA reconfiguration controller sets the active slot bits 7204 input to the controller 720 to indicate the activity or inactivity of the partial reconfiguration slots at the FPGA 20.

In example operation, the segment length parser 72 may receive segment descriptor information from the segment descriptor table 70. If the on/off bit 7202 for the corresponding partial reconfiguration slot is set to ON, then the segment length parser 72 outputs the segment descriptor information with a modified segment length field. The segment length parser 72 may modify the segment length field by masking (e.g., zeroing) one or more bits of the segment length field based on the active slot bits 7204 input to the controller 720. By utilizing masking of one or more bits of the segment length field, the size of a memory segment allocated to a memory segment may be reduced by reducing the maximum number of pages that compose the memory segment allocated to the partial reconfiguration slot.

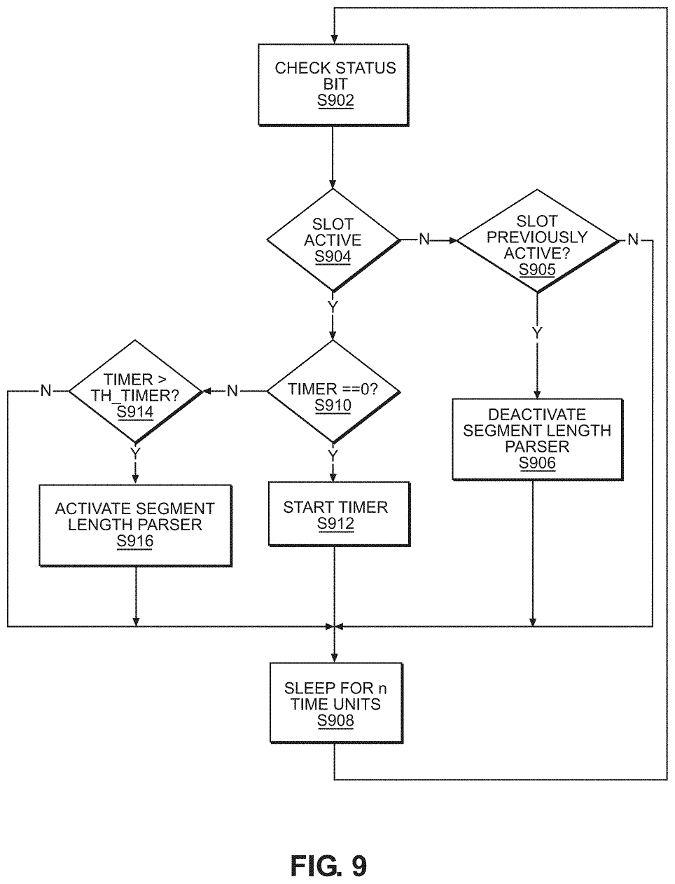

FIG. 9 is a flow chart illustrating a method for determining whether to apply segment length parsing for a given partial reconfiguration slot according to example embodiments. The method shown in FIG. 9 may be performed by the memory manager 30 shown in FIG. 1. For example purposes, the example embodiment shown in FIG. 9 will be described with regard to partial reconfiguration slot 21 and memory segment 401 shown in FIG. 1. It should be understood, however, that the method shown in FIG. 9 may be performed for any or all of the partial reconfiguration slots shown in FIG. 1. Moreover, the process for any or all of the partial reconfiguration slots 21-24 may be performed in parallel.

The process shown in FIG. 9 may be performed periodically for each of the partial reconfiguration slots of the FPGA 20. In one example, the periodicity of the method shown in FIG. 9 may be a multiple of the reconfiguration time for a partial reconfiguration slot of the FPGA 20 (e.g., about 1-10 ms or more).

Referring to FIG. 9, at step S902 the memory manager 30 checks a status bit for the partial reconfiguration slot 21. The status bit indicates whether the partial reconfiguration slot 21 is currently active. In one example, the status bit may be set by the network orchestrator 10 according to whether the partial reconfiguration slot 21 is currently active (e.g., resources of the partial reconfiguration slot 21 are currently being utilized). The status bit may be stored in a control register (not shown) at the FPGA 20. In one example, the FPGA 20 may retain at least two status bits (e.g., a current status bit and a most recent previous status bit) for the partial reconfiguration slot 21.

If the status bit indicates that the partial reconfiguration slot 21 is inactive, then at step S905 the memory manager 30 determines whether the partial reconfiguration slot 21 was previously active (e.g., the status bit value has changed from active to inactive since the last iteration of the process the memory manager 30).

If the partial reconfiguration slot 21 was not previously active, then at step S908 the memory manager 30 ends the current iteration and proceeds to ‘sleep’ or wait for a sleep interval (n time units), after which the process returns to step S902 to perform a subsequent iteration of the process. The sleep interval is equal to the periodicity of the method shown in FIG. 9.

Returning to step S905, if the partial reconfiguration slot 21 was previously active, then at step S906 the memory manager 30 deactivates the segment length parser 72 by setting the on/off bit to OFF (e.g., 1 or 0). In this case, the on/off bit 7202 input to the controller 72 during address translation deactivates the segment length parser 72 such that the segment length parser 72 is not utilized in translating the received virtual memory address information from the MMU 210 of the partial reconfiguration slot 21. The process then proceeds to step S908 and continues as discussed herein.

Returning to step S904, if the status bit indicates that the partial reconfiguration slot 21 is currently active, then the memory manager 30 checks a current value of a timer TIMER (e.g., a clock or counter circuit (not shown)) at the FPGA 20 indicating the length of time the partial reconfiguration slot 21 has been active. If the timer TIMER is at 0 (TIMER ==0, indicating, e.g., the partial reconfiguration slot 21 has only just become active), then at step 5912 the memory manager 30 initiates the timer TIMER to track the active time of the partial reconfiguration slot 21. The process then proceeds to step S908 and continues as discussed herein.

Returning to step S910, if the activity timer TIMER is not TIMER ==0 (the partial reconfiguration slot was already active), then at step S914 the memory manager 30 determines whether the current value of the timer TIMER is greater than an activity timer threshold value TH_TIMER. In one example, the activity timer threshold value TH_TIMER may be a multiple of the FPGA clock for the FPGA 20 (e.g., on the order of microseconds).

If the value of the timer TIMER is not greater than (is less than or equal to) the activity timer threshold value TH_TIMER, then the process proceeds to step 5908 and continues as discussed herein.

Returning to step S914, if the value of the timer TIMER is greater than the activity timer threshold value TH_TIMER, then at step S916 the memory manager 30 activates the segment length parser 72 by setting the on/off bit for the partial reconfiguration slot 21 to ON (e.g., 1 or 0). In this case, the on/off bit 7202 input to the controller 72 during address translation activates the segment length parser 72 such that the segment length parser 72 is utilized in translating the received virtual memory address information from the MMU 210 of the partial reconfiguration slot 21. The process then proceeds to step S908 and continues as discussed herein.

As described above, the method shown in FIG. 9 may be utilized to activate or deactivate the segment length parser 72 by setting the on/off bit for the partial reconfiguration slot 21 accordingly.

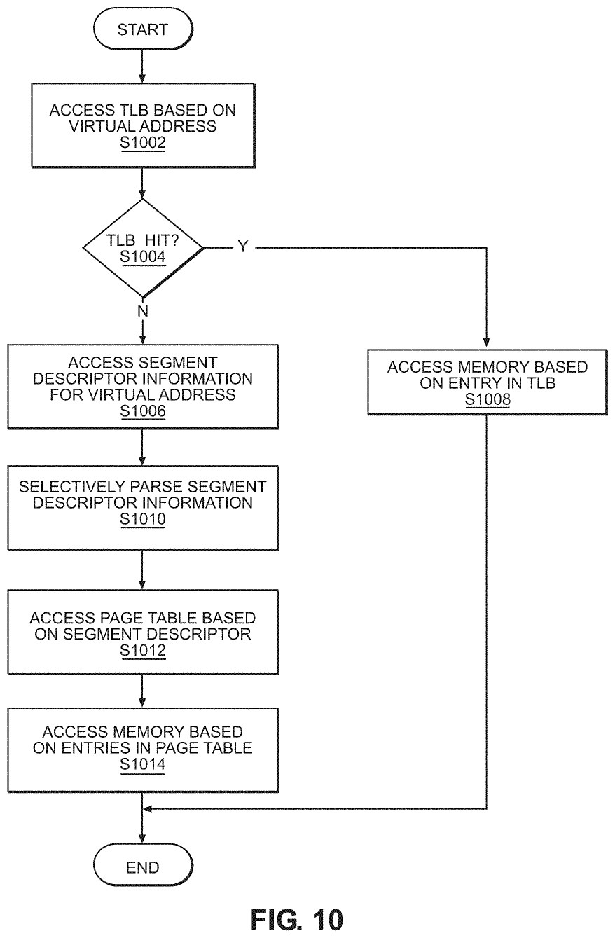

FIG. 10 is a flow chart illustrating a method for accessing FPGA main memory according to example embodiments. The method shown in FIG. 10 may be performed by the memory manager 30 shown in FIG. 1. For example purposes, the example embodiment shown in FIG. 10 will be described with regard to the partial reconfiguration slot 21 and memory segment 401 shown in FIG. 1 as well as the memory manager 30 and main memory 40 shown in FIGS. 1 and 7. It should be understood, however, that the method shown in FIG. 10 may be performed for any or all of the partial reconfiguration slots shown in FIG. 1.

Referring to FIG. 10, in response to receiving virtual address information associated with a memory access operation from the MMU 210, at step S1002 the memory manager 30 accesses the TLB 78 to determine whether the virtual address information is present in the TLB 78.

If the virtual address information is determined to be present in the TLB 78 (TLB hit) at step S1004, then at step S1008 the memory manager 30 accesses the main memory 40 to perform the memory access operation based on the entries in the TLB 78 and the process terminates.

Returning to step S1004, if the virtual address information is determined not to be present in the TLB 78 (TLB miss), then at step S1006 the memory manager 30 accesses the segment descriptor table 70 to obtain the segment descriptor information based on the segment number field included in the received virtual address information.

At step S1010, the memory manager 30 (via the segment length parser 72) selectively parses the segment descriptor information obtained from the segment descriptor table 70 based on the current value of the on/off bit 7202 for the partial reconfiguration slot 21. As discussed above, if the on/off bit is set to OFF, then the segment length parser 72 does not parse the segment descriptor information and the segment descriptor information is utilized by the memory manager 30 as is. If, however, the on/off bit 7202 is set to ON, then the segment length parser 72 parses the segment descriptor information accordingly.

In more detail, for example, if the on/off bit 7202 is set to ON, then at step S1010 the segment length parser 72 parses the segment length field of the segment descriptor information. In one example, the segment length parser 72 masks (e.g., zeroes) one or more bits of the segment length field of the segment descriptor information obtained from the segment descriptor table based on the number of active partial reconfiguration slots at the FPGA 20. As mentioned above, the number of active partial reconfiguration slots may be indicated by the active slot bits 7204 input to the controller 722, and the segment length field defines the memory segment length in terms of number of pages. With few active partial reconfiguration slots, a larger number of bits in this the segment length field may be masked (e.g., zeroed), thereby providing more pages to the memory segment for the particular partial reconfiguration slot.

At step S1012, the memory manager 30 accesses the page table for the memory based on the (parsed or unparsed) segment descriptor information to obtain one or more entries for accessing the main memory 40.

At step S1014, the memory manager 30 accesses the main memory 40 based on the obtained entries from the page table as in a conventional virtual memory system.

As discussed above, according to example embodiments, the memory manager 30 may also manage the virtual memory segmentation of the main memory 40. For example, the memory manager 30 may divide the main memory 40 into the plurality of virtual memory segments 401-404, one per partial reconfiguration slot, and allocate or assign a virtual memory segment to each of the partial reconfiguration slots 21-24. The memory manager 30 may then add, remove or dynamically adjust the size of each virtual memory segment 401-404 as needed based on the number of active partial reconfiguration slots and the memory needs of the active partial reconfiguration slots.

In one example, when a new partial reconfiguration slot becomes active (e.g., switches from inactive to active), the length of memory segments allocated to other active partial reconfiguration slots may be reduced to add a memory segment for a newly active partial reconfiguration slot. The size of the memory segment to be allocated to the newly active partial reconfiguration slot may be specified by the FPGA OS (not shown). The size may be modified at runtime by the network orchestrator 10 via the FPGA OS. Thus, the FPGA OS (or other FPGA management software layer) may check the number of pages currently in use for each other active partial reconfiguration slot. If the number of pages currently in use is larger than the new (reduced) size of the memory segments, then FPGA OS selects some pages to evict from the main memory 40. In this case, the FPGA OS also guarantees coherency of the TLB 78 and page tables for other partial reconfiguration slots. For example, if the TLB 78 and/or page tables for other partial reconfiguration slots contain references to the pages to be evicted, then these references are cleared. Other hardware (e.g., caches) may also be updated (e.g., caches, etc., if present) as needed.

When a partial reconfiguration slot becomes inactive (e.g., when a partial reconfiguration slot has been inactive for greater than a threshold inactivity period), the memory manager 30 removes (deallocates), from the main memory 40, the memory segment allocated to the now inactive partial reconfiguration slot, and the size of the memory segments allocated to the remaining active partial reconfiguration slots may be increased. Thus, the FPGA OS may select a number of pages to page in or simply do nothing. In the latter case, upon a future page miss, a given number of nearby pages may be paged in together with the desired page. Whenever new pages are paged in, the TLB 78 and the page tables are updated accordingly, to help ensure coherency of the virtual memory system.

According to example embodiments, when a partial reconfiguration slot is activated/deactivated, the memory manager 30 adjusts the memory segment size allocated to each active partial reconfiguration slot. The memory manager 30 may adjust the memory segment size based on at least two memory size adjustment parameters. The memory size adjustment parameters may include a number of currently active partial reconfiguration slots and the actual use of the memory by each active partial reconfiguration slot. In the case of the number of active partial reconfiguration slots, each activation of a partial reconfiguration slot results in a reduction of the size of the memory segment allocated to each previously active partial reconfiguration slot. In the case of the use of the memory by each active partial reconfiguration slot, this parameter may be provided by the FPGA OS. In one example, this parameter may be retrieved by a smart analysis of the memory accesses (e.g., monitoring traffic to/from the FPGA memory), and enables the memory manager 30 to reduce the lengths of memory segments allocated to partial reconfiguration slots deemed to require less memory footprint, while increasing the lengths of memory segments allocated to partial reconfiguration slots deemed to require a larger memory footprint.

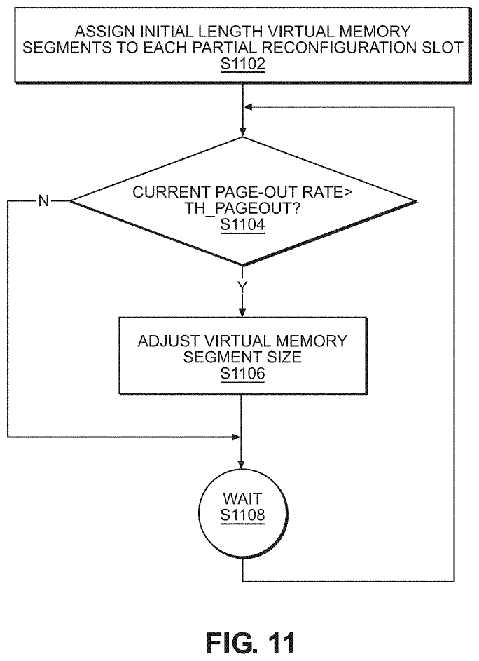

FIG. 11 is a flow chart illustrating a method for dynamically managing virtual memory segments in a FPGA memory according to example embodiments. The method shown in FIG. 11 may be performed by the memory manager 30 shown in FIG. 1. For example purposes, the example embodiment shown in FIG. 11 will be described with regard to FPGA architecture 1 shown in FIG. 1. However, example embodiments should not be limited to this example. Moreover, in some instances, the method shown in FIG. 11 will be discussed with regard to a single virtual memory segment 401 and partial reconfiguration slot 21 for example purposes. However, it should be understood that the method may be performed for any and/or all virtual memory segments 401- 404 and partial reconfiguration slots 21-24 of the FPGA 20.

Referring to FIG. 11, at step S1102, (e.g., at system boot or initialization) the memory manager 30 assigns virtual memory segments 401, 402, 403 and 404 to partial reconfiguration slots 21, 22, 23, 24, respectively. In one example, each of the virtual memory segments 401, 402, 403 and 404 may have a same length L. In another, example, as discussed above the memory manager 30 may determine the length of each virtual memory segment 401-404 based on memory needs and/or requirements of the partial reconfiguration slots 21-24.

At step S1104, after a delay or waiting period, the memory manager 30 checks whether a current page-out rate for a virtual memory segment and corresponding partial reconfiguration slot is greater than a page-out rate threshold TH_PAGEOUT. The page-out rate threshold TH_PAGEOUT will be discussed in more detail below. The delay or waiting period may be a time window having the same or substantially the same length as the ‘sleep’ time discussed herein with regard to FIG. 9 (e.g., a multiple of the reconfiguration time for a partial reconfiguration slot of the FPGA 20), although example embodiments should not be limited to this example.

According to example embodiments, the memory manager 30 may continuously monitor the page-out rate for each active partial reconfiguration slot. The page-out rate for a partial reconfiguration slot is defined as the number of pages being swapped out of the virtual memory segment of the FPGA main memory 40 assigned to a given partial reconfiguration slot during a given time window. In this example, the time window is the delay or waiting period discussed above.

In one example, the memory manager 30 maintains a counter for each partial reconfiguration slot. During the time window, for each respective partial reconfiguration slot, the memory manager 30 updates the corresponding counter each time a page is swapped out of a virtual memory segment associated with the respective partial reconfiguration slot. At the end of the time window, the memory manager 30 computes the average page-out rate for the FPGA 20 as the sum of page-out rates of all active partial reconfiguration slots during the time window divided by the number of active partial reconfiguration slots at the FPGA 20 during the time window. The memory manager 30 then resets the counter for each (active) partial reconfiguration slot to zero.

The page-out rate threshold TH_PAGEOUT may be based on an average page-out rate for the FPGA 20 during a given time window. For example, the page-out threshold may be about 120% of the average page-out rate for the FPGA 20 in the given time window. Thus, the page-out rate threshold TH_PAGEOUT may change dynamically from one time window to the next.

Returning to FIG. 11, if the current page-out rate for the partial reconfiguration slot is greater than the page-out rate threshold TH_PAGEOUT, then at step S1106 the memory manager 30 adjusts the sizes of the virtual memory segment 401-404 as needed based on the average page-out rate. In one example, the memory manager 30 adjusts the sizes of the virtual memory segment 401-404 as needed to move the page-out rate of each partial reconfiguration slot 21-24 as close as possible to the average page-out rate.

A more detailed example of step S1106 will now be described with regard to partial reconfiguration slots 21 and 22 and virtual memory segments 401 and 402, wherein partial reconfiguration slot 22 has the lowest page-out rate during a most recent time window.

In this example, when the page-out rate for partial reconfiguration slot 21 exceeds the page-out rate threshold TH_PAGEOUT (e.g., 120% of the average page-out rate), the memory manager 30 increases the size of the virtual memory segment 401 by U1 units, and decreases the length of the virtual memory segment 402 by U2units. The amounts U1 and U2 may be defined proportionally relative to the default segment length L of the virtual memory segments 401-404. In one example, Ux may be equal to L/10; that is, Ux may be 10% of the default segment length L for a partial reconfiguration slot Sx.

Once having adjusted the virtual memory segment size as needed at step S1106, the memory manager 30 waits for a waiting period at step S1108. In one example, the waiting period may be equal or substantially equal to the time window. However, example embodiments should not be limited to this example. At the end of the waiting period, the process returns to step S1104 and continues as discussed herein.

Returning to step S1104, if the current page-out rate for the partial reconfiguration slot is less than or equal to the page-out rate threshold TH_PAGEOUT, then the memory manager 30 need not adjust the size of the virtual memory segment associated with the partial reconfiguration slot. In this case, the process proceeds to step S1108 and continues as discussed herein.

One or more example embodiments may enable use of virtualized memory at a FPGA independently from a host OS. One or more example embodiments may also provide automatic management and/or sharing of memory between several partial reconfiguration slots and/or users, automatic allocation of memory segments to a partial reconfiguration slot and/or user to reduce page faults and thus reduce workload latencies, the use of virtual addresses in hardware to enhance security between partial reconfiguration slots and/or users and/or reduced workload latencies to increase hardware use and profitability.

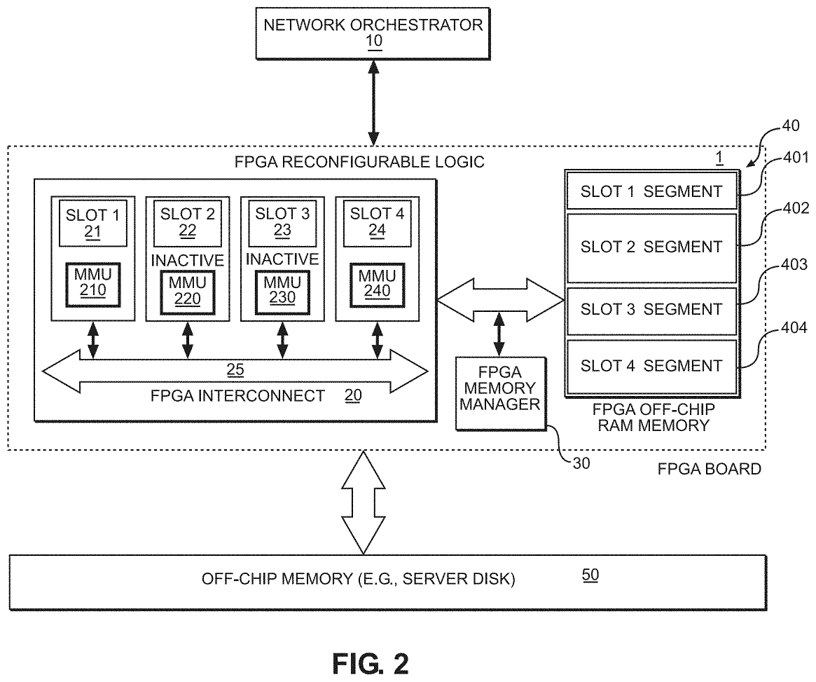

FIGS. 2-4 illustrate example memory segmentations of a FPGA memory according to example embodiments.

FIG. 2 illustrates a virtual memory layout after time t2, wherein partial reconfiguration slot 22 and partial reconfiguration slot 23 have become inactive. Upon occurrence of these events, the virtual memory segments 402 and 403 of partial reconfiguration slot 22 and 23, respectively, are empty.

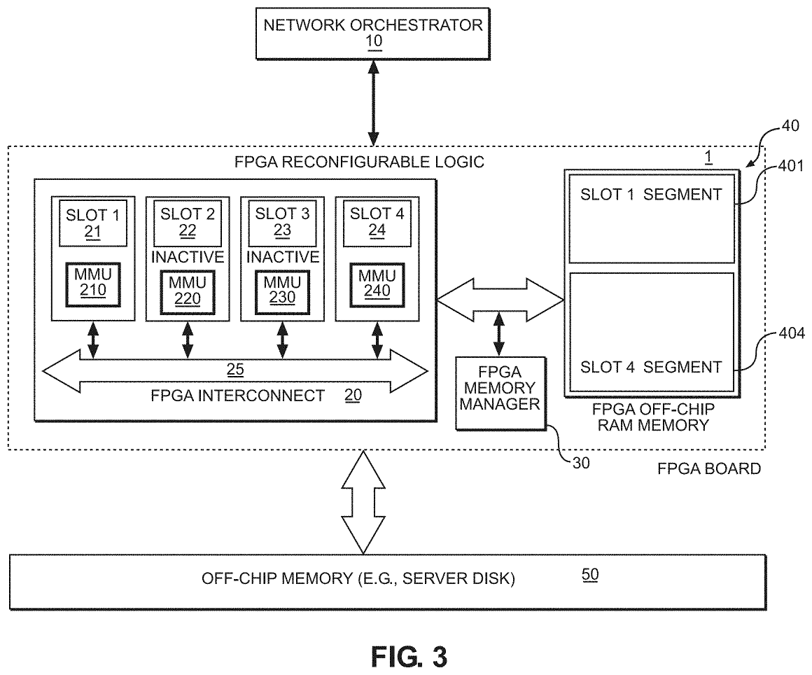

FIG. 3 shows a subsequent virtual memory layout after the memory manager 30 detects inactivity of partial reconfiguration slots 22 and 23, and adjusts (e.g., increases) the memory segments 401 and 404 allocated to remaining active partial reconfiguration slots 21 and 24, respectively. In this example, page faults may be reduced for these active partial reconfiguration slots and network service latency may be decreased relative to the scenario in FIG. 1.

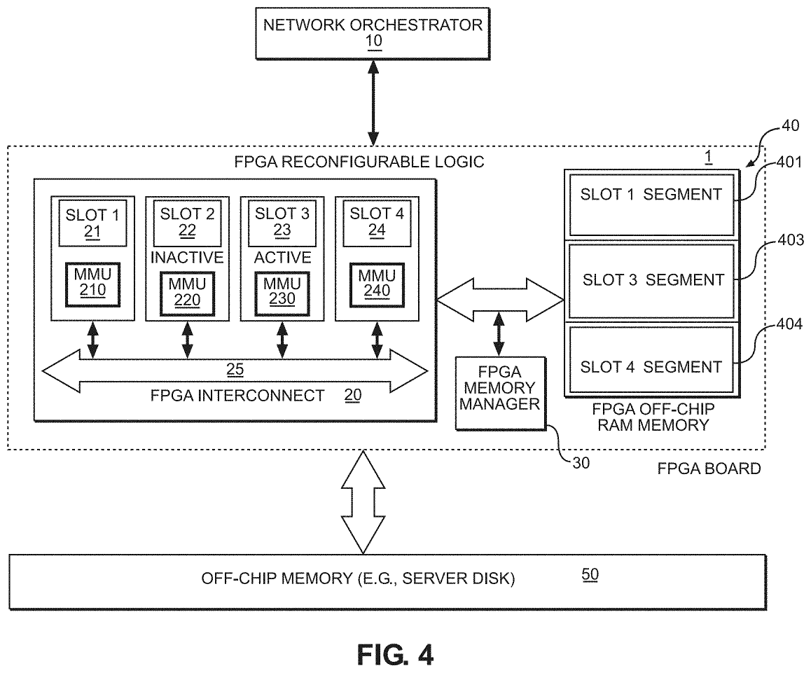

FIG. 4 shows a virtual memory layout when partial reconfiguration slot 23 becomes active again (e.g., the network orchestrator 10 allocates a new network function or reallocates a previous one). In this case, as discussed above, the memory manager 30 detects the re-activation of the partial reconfiguration slot 23, and dynamically adjusts (e.g., decreases) the size of the virtual memory segments 401 and 404 allocated to currently active partial reconfiguration slots 21 and 24, respectively, to host a new memory segment for partial reconfiguration slot 23. In this case, partial reconfiguration slot 22 remains inactive, and thus, a dedicated memory segment need not be allocated to the partial reconfiguration slot 22.

Although the terms first, second, etc. may be used herein to describe various elements, these elements should not be limited by these terms. These terms are only used to distinguish one element from another. For example, a first element could be termed a second element, and similarly, a second element could be termed a first element, without departing from the scope of this disclosure. As used herein, the term “and/or,” includes any and all combinations of one or more of the associated listed items.

When an element is referred to as being “connected,” or “coupled,” to another element, it can be directly connected or coupled to the other element or intervening elements may be present. By contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting. As used herein, the singular forms “a,” “an,” and “the,” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Specific details are provided in the following description to provide a thorough understanding of example embodiments. However, it will be understood by one of ordinary skill in the art that example embodiments may be practiced without these specific details. For example, systems may be shown in block diagrams so as not to obscure the example embodiments in unnecessary detail. In other instances, well- known processes, structures and techniques may be shown without unnecessary detail in order to avoid obscuring example embodiments.

As discussed herein, illustrative embodiments will be described with reference to acts and symbolic representations of operations (e.g., in the form of flow charts, flow diagrams, data flow diagrams, structure diagrams, block diagrams, etc.) that may be implemented as program modules or functional processes include routines, programs, objects, components, data structures, etc., that perform particular tasks or implement particular abstract data types and may be implemented using existing hardware at, for example, existing network apparatuses, elements or entities including cloud-based data centers, computers, cloud-based servers, or the like. Such existing hardware may be processing or control circuitry such as, but not limited to, one or more processors, one or more Central Processing Units (CPUs), one or more controllers, one or more arithmetic logic units (ALUs), one or more digital signal processors (DSPs), one or more microcomputers, one or more field programmable gate arrays (FPGAs), one or more System-on-Chips (SoCs), one or more programmable logic units (PLUs), one or more microprocessors, one or more Application Specific Integrated Circuits (ASICs), or any other device or devices capable of responding to and executing instructions in a defined manner.

Although a flow chart may describe the operations as a sequential process, many of the operations may be performed in parallel, concurrently or simultaneously. In addition, the order of the operations may be re-arranged. A process may be terminated when its operations are completed, but may also have additional steps not included in the figure. A process may correspond to a method, function, procedure, subroutine, subprogram, etc. When a process corresponds to a function, its termination may correspond to a return of the function to the calling function or the main function.

As disclosed herein, the term “storage medium,” “computer readable storage medium” or “non-transitory computer readable storage medium” may represent one or more devices for storing data, including read only memory (ROM), random access memory (RAM), magnetic RAM, core memory, magnetic disk storage mediums, optical storage mediums, flash memory devices and/or other tangible machine-readable mediums for storing information. The term “computer-readable medium” may include, but is not limited to, portable or fixed storage devices, optical storage devices, and various other mediums capable of storing, containing or carrying instruction(s) and/or data.

Furthermore, example embodiments may be implemented by hardware, software, firmware, middleware, microcode, hardware description languages, or any combination thereof. When implemented in software, firmware, middleware or microcode, the program code or code segments to perform the necessary tasks may be stored in a machine or computer readable medium such as a computer readable storage medium. When implemented in software, a processor or processors will perform the necessary tasks. For example, as mentioned above, according to one or more example embodiments, at least one memory may include or store computer program code, and the at least one memory and the computer program code may be configured to, with at least one processor, cause a network apparatus, network element or network device to perform the necessary tasks. Additionally, the processor, memory and example algorithms, encoded as computer program code, serve as means for providing or causing performance of operations discussed herein.

A code segment of computer program code may represent a procedure, function, subprogram, program, routine, subroutine, module, software package, class, or any combination of instructions, data structures or program statements. A code segment may be coupled to another code segment or a hardware circuit by passing and/or receiving information, data, arguments, parameters or memory contents. Information, arguments, parameters, data, etc. may be passed, forwarded, or transmitted via any suitable technique including memory sharing, message passing, token passing, network transmission, etc.

The terms “including” and/or “having,” as used herein, are defined as comprising (i.e., open language). The term “coupled,” as used herein, is defined as connected, although not necessarily directly, and not necessarily mechanically. Terminology derived from the word “indicating” (e.g., “indicates” and “indication”) is intended to encompass all the various techniques available for communicating or referencing the object/information being indicated. Some, but not all, examples of techniques available for communicating or referencing the object/information being indicated include the conveyance of the object/information being indicated, the conveyance of an identifier of the object/information being indicated, the conveyance of information used to generate the object/information being indicated, the conveyance of some part or portion of the object/information being indicated, the conveyance of some derivation of the object/information being indicated, and the conveyance of some symbol representing the object/information being indicated.

According to example embodiments, network apparatuses, elements or entities including cloud-based data centers, computers, cloud-based servers, or the like, may be (or include) hardware, firmware, hardware executing software or any combination thereof. Such hardware may include processing or control circuitry such as, but not limited to, one or more processors, one or more CPUs, one or more controllers, one or more ALUs, one or more DSPs, one or more microcomputers, one or more FPGAs, one or more SoCs, one or more PLUs, one or more microprocessors, one or more ASICs, or any other device or devices capable of responding to and executing instructions in a defined manner.

Benefits, other advantages, and solutions to problems have been described above with regard to specific embodiments of the invention. However, the benefits, advantages, solutions to problems, and any element(s) that may cause or result in such benefits, advantages, or solutions, or cause such benefits, advantages, or solutions to become more pronounced are not to be construed as a critical, required, or essential feature or element of any or all the claims.

Reference is made in detail to embodiments, examples of which are illustrated in the accompanying drawings, wherein like reference numerals refer to the like elements throughout. In this regard, the example embodiments may have different forms and should not be construed as being limited to the descriptions set forth herein. Accordingly, the example embodiments are merely described below, by referring to the figures, to explain example embodiments of the present description. Aspects of various embodiments are specified in the claims.

1. -20. (canceled).

21. A programmable logic device comprising:
a plurality of reconfigurable slots programmed to execute functions requested by a plurality of users, the plurality of reconfigurable slots allocated among the plurality of users;
a memory divided into a plurality of memory segments, the plurality of memory segments allocated among the plurality of reconfigurable slots; and
a memory management circuit configured to dynamically adjust the plurality of memory segments based on at least one of activity or memory requirements of the plurality of reconfigurable slots.

22. The programmable logic device of claim 21, wherein the memory management circuit is configured to adjust a spatial allocation of the plurality of memory segments among the plurality of reconfigurable slots based on the at least one of activity or memory requirements of the plurality of reconfigurable slots.

23. The programmable logic device of claim 22, wherein the memory management circuit is configured to adjust the spatial allocation of the plurality of memory segments by adjusting a size of at least one of the plurality of memory segments.

24. The programmable logic device of claim 21, wherein each of the plurality of memory segments has a variable segment size.

25. The programmable logic device of claim 21, wherein the plurality of memory segments include a first memory segment allocated to a first reconfigurable slot among the plurality of reconfigurable slots; and
the memory management circuit is configured to
determine that the first reconfigurable slot has become inactive, and
reallocate the first memory segment among remaining ones of the plurality of reconfigurable slots in response to determining that the first reconfigurable slot has become inactive.

26. The programmable logic device of claim 25, wherein the memory management circuit is configured to
determine that the first reconfigurable slot has become active after having been inactive, and
reallocate a portion of at least one of the plurality of memory segments to the first reconfigurable slot in response to determining that the first reconfigurable slot has become active.

27. The programmable logic device of claim 21, wherein
the plurality of memory segments include a first memory segment allocated to a first reconfigurable slot among the plurality of reconfigurable slots; and
the memory management circuit is configured to
determine that the memory requirements for the first reconfigurable slot have changed, and
reallocate, to the first reconfigurable slot, at least a portion of a memory segment allocated to a second reconfigurable slot in response to determining that the memory requirements for the first reconfigurable slot have changed.

28. The programmable logic device of claim 21, wherein the memory management circuit is configured to manage the plurality of memory segments independent of an external host device.

29. The programmable logic device of claim 21, wherein the programmable logic device is a field-programmable gate array (FPGA).

30. The programmable logic device of claim 21, wherein the memory management circuit comprises:
a segment descriptor table storing segment descriptor information for the plurality of memory segments, wherein
segment descriptor information for a memory segment, among the plurality of memory segments, includes at least a segment length of the memory segment, and
the segment descriptor table is configured to output the segment descriptor information for the memory segment based on received virtual address information including a segment number indicative of the memory segment; and
a segment length parser circuit configured to
parse the segment descriptor information for the memory segment to obtain parsed segment descriptor information, and
access the memory segment based on the parsed segment descriptor information.

31. The programmable logic device of claim 30, wherein
the segment length includes a plurality of bits, and
the segment length parser circuit is configured to parse the segment descriptor information for the memory segment by masking a portion of the plurality of bits based on a number of the plurality of reconfigurable slots that are currently active.

32. The programmable logic device of claim 31, wherein
the segment length includes a plurality of bits, and
the segment length parser circuit is configured to dynamically adjust sizes of the plurality of memory segments based on a masking of a portion of the plurality of bits based on a number of the plurality of reconfigurable slots that are currently active.

33. The programmable logic device of claim 30, wherein
the segment descriptor information includes virtual address information for the memory segment, and
the segment length parser circuit is configured to dynamically parse the virtual address information for the memory segment based on a number of the plurality of reconfigurable slots that are currently active and a variable size of the plurality of memory segments.

34. A method for managing memory at a programmable logic device including a plurality of reconfigurable slots and a memory, the plurality of reconfigurable slots programmed to execute functions requested by a plurality of users, and the memory including a plurality of variable-sized segments, wherein the method comprises:
assigning a variable-sized segment, from among the plurality of variable- sized segments, to each of a plurality of reconfigurable slots, each of the plurality of users assigned to at least one of the plurality of reconfigurable slots;
determining that a first reconfigurable slot, among the plurality of reconfigurable slots, has become inactive; and
dynamically adjusting sizes of the plurality of variable-sized segments in response to determining that the first reconfigurable slot has become inactive.

35. The method of claim 34, wherein
a first variable-sized memory segment is allocated the first reconfigurable slot,
a second variable-sized memory segment is allocated a second reconfigurable slot, among the plurality of reconfigurable slots, and
the dynamically adjusting includes
re-allocating at least a portion of the first variable-sized memory segment to the second reconfigurable slot to increase a size of the second variable-sized memory segment in response to determining that the first reconfigurable slot has become inactive.

36. The method of claim 34, further comprising:
determining that the first reconfigurable slot has become active after having been inactive; and wherein
the dynamically adjusting includes
creating a first variable-sized memory segment allocated to the first reconfigurable slot by reallocating at least a portion of at least a second variable-sized memory segment allocated to a second reconfigurable slot in response to determining that the first reconfigurable slot has become active.

37. The method of claim 34, wherein the dynamically adjusting dynamically adjusts the sizes of the plurality of variable-sized segments independent of an external host device.

38. The method of claim 34, wherein the determining determines that the first reconfigurable slot has become inactive based on a status bit indicating an activity of the first reconfigurable slot.

39. The method of claim 34, wherein the programmable logic device is a FPGA.

40. A method for access a main memory of a programmable logic device including a plurality of partial reconfiguration slots, the method comprising:
accessing segment descriptor information associated with a first partial reconfiguration slot among the plurality of partial reconfiguration slots based on virtual address information received from the first partial reconfiguration slot;
parsing the segment descriptor information based on a number of active partial reconfiguration slots among the plurality of partial reconfiguration slots to obtain parsed segment descriptor information;
accessing a page table for the first partial reconfiguration slot based on the parsed segment descriptor information to obtain one or more entries for accessing the main memory; and
accessing the main memory based on the one or more entries for accessing the main memory.
